(19) United States
(12) Patent Application Publication
(10) Pub. No.: US 2025/0282609 A1
(43) Pub. Date: Sep. 11, 2025

(54) MICROELECTROMECHANICAL SYSTEM DEVICE WITH OFFSET MIRROR

(71) Applicant: TEXAS INSTRUMENTS INCORPORATED, Dallas, TX (US)

(72) Inventors: William C. MCDONALD, Allen, TX (US); James HALL, Parker, TX (US); Terry A. BARTLETT, Dallas, TX (US)

(21) Appl. No.: 18/930,259

(22) Filed: Oct. 29, 2024

Related U.S. Application Data
(60) Provisional application No. 63/562,720, filed on Mar. 8, 2024.

(51) Int. Cl. B81B 3/00; G02B 26/08

(52) U.S. Cl. CPC B81B 3/0083; G02B 26/0833; B81B 2201/042; B81B 2203/0118; B81B 2203/0154; B81B 2203/0361; B81B 2203/04; B81B 2207/053; B81B 2207/094

(57) ABSTRACT

A microelectromechanical system (MEMS) device includes: a mechanical layer; a mirror; and a mirror via coupling the mechanical layer and the mirror. The mirror is laterally offset from the mechanical layer in a direction.

### CROSS-REFERENCE TO RELATED APPLICATIONS

This application claims priority to U.S. Provisional Application No. 63/562,720, filed Mar. 8, 2024, entitled “MICROMIRROR DESIGN WITH OFFSET MIRROR FOR CONTRAST IMPROVEMENT.” which is hereby incorporated herein by reference in its entirety.

### BACKGROUND

Some microelectromechanical system (MEMS) devices are used in a spatial light modulator (SLM), such as a digital micromirror device (DMD) to form an array of pixels. An example MEMS device selectively switches a mirror between an on position and an off position responsive to control data. The contrast of a display or projector with an SLM is negatively affected by off-state reflectivity of a MEMS device.

### SUMMARY

In an example, a microelectromechanical system (MEMS) device includes: a mechanical layer; a mirror; and a mirror via coupling the mechanical layer and the mirror, wherein the mirror is laterally offset from the mechanical layer in a direction.

In another example, a MEMS device includes: an electrode layer; a mechanical layer; hinge vias coupling the electrode layer and the mechanical layer; a mirror; and a mirror via coupling the mechanical layer and the mirror. The mirror has a first position when the MEMS device is in an on state. The mirror has a second position when the MEMS device is in an off state. The mirror is laterally offset relative to the mechanical layer in a direction.

In yet another example, a MEMS device includes: an electrode layer; a mechanical layer; hinge vias coupling the electrode layer and the mechanical layer; a mirror; and a mirror via coupling the mechanical layer and the mirror, wherein the mirror is laterally offset relative to the mechanical layer in a direction.

### BRIEF DESCRIPTION OF THE DRAWINGS

FIG. 1 is a block diagram of a system in accordance with various examples.

FIG. 2A is an exploded view of a MEMS device in accordance with various examples.

FIG. 2B is a perspective view of the MEMS device of FIG. 2A.

FIG. 3A is an exploded view of a MEMS device in accordance with various examples.

FIG. 3B is a perspective view of the MEMS device of FIG. 3A.

FIG. 4 is a cross-sectional view of the MEMS device of FIG. 3B in an on-state.

FIG. 5 is a cross-sectional view of the MEMS device of FIG. 3B in an off-state.

FIG. 6 is a top view of the offset mirror relative to a center position for the MEMS device of FIG. 3B.

FIG. 7A is an incoming light angle view of some of a pixel array with offset mirrors in an on position.

FIG. 7B is a projection aperture view of the pixel array of FIG. 7A with offset mirrors in an on position.

FIG. 7C is an incoming light angle view of the pixel array of FIG. 7A with offset mirrors in an off position.

FIG. 7D is a projection aperture view of the pixel array of FIG. 7A with offset mirrors in an off position.

FIG. 8 is a perspective view of a MEMS device in accordance with various examples.

FIG. 9A is a cross-sectional view of the MEMS device of FIG. 8 in an on-state.

FIG. 9B is a cross-sectional view of the MEMS device of FIG. 8 in an off-state.

FIG. 10 is a top view of the offset mirror of the MEMS device of FIG. 9B relative to a center position.

FIG. 11A is incoming light angle view of some of a pixel array with offset mirrors in an on position.

FIG. 11B is a projection aperture view of the pixel array of FIG. 11A with offset mirrors in an on position.

FIG. 11C is an incoming light angle view of the pixel array of FIG. 11A with offset mirrors in an off position.

FIG. 11D is a projection aperture view of the pixel array of FIG. 11A with offset mirrors in an off position.

FIG. 12 is a top view of sculpted offset mirrors in accordance with various examples.

FIG. 13 is a flowchart showing a MEMS device fabrication method in accordance with various examples.

### DETAILED DESCRIPTION

The same reference numbers or other reference designators are used in the drawings to designate the same or similar features. Such features may be the same or similar either by function and/or structure.

Described herein is a microelectromechanical system (MEMS) device with layers. Example layers include an electrode layer, a mechanical layer, and a mirror, where vias are coupled between components of such layers. Example vias include a mirror via, hinge vias, spring tip vias, and raised electrode vias. An example MEMS device also includes a mirror that is offset in a direction relative to a target component (or components) of the MEMS device. Such mirrors are sometimes referred to herein as “offset mirrors”. In some examples, the amount of offset and the direction are selected to increase coverage (reduce exposure) of the target component relative to a projection aperture while the MEMS device is in an off-state. In some examples, the target component is a reflective component of a mechanical layer, such as a hinge, a raised electrode, and/or a spring tip. Increasing coverage of the target component while the MEMS device is in the off-state relative to the projection aperture, reduces the amount of light that reaches the projection aperture while the MEMS device is in the off-state. The result is a darker off-state for MEMS device relative to the projection aperture, resulting in improved on/off contrast for a MEMS device.

In some examples, each MEMS device is a pixel. In different examples, such MEMS devices are organized into a pixel array for a spatial light modulator (SLM), such as a digital micromirror device (DMD). During operations, the SLM receives data from a controller to control on/off states of pixels of the pixel array. In the off-state, the offset mirrors reduce reflectivity of respective target components relative to a projection aperture. In some examples, the projection aperture is part of a projector or display that includes the SLM, the controller, and a light source. By using a pixel array with offset mirrors, the contrast of a projector or display is increased (e.g., up to 20% or more) without significant redesign of a MEMS device. For example, a MEMS device layout may be modified to include an offset mirror without changing the layout of mechanical layer components and/or electrode layer components. In other examples, a MEMS device layout may include some modifications to mechanical layer components and/or electrode layer components, where use of an offset mirror reduces the amount of modification needed to achieve a target contrast.

In some examples, a mirror via center is aligned with an offset mirror center and is not aligned with a mechanical layer center. In such examples, aligning the mirror via center with the offset mirror center and not with the mechanical layer center may involve some changes to the mechanical layer layout (e.g., increasing cost and limiting spacing and/or size reduction options for MEMS device fabrication) while ensuring the offset mirror is balanced on the mirror via and has consistent movement. In other examples, a mirror via center is aligned with a mechanical layer center and is not aligned with an offset mirror center. In such examples, aligning the mirror via center with the mechanical layer and not with the offset mirror center facilitates mechanical layer layout (e.g., maintaining cost, spacing and/or size reduction options for MEMS device fabrication) while possibly increasing offset mirror imbalance and related issues.

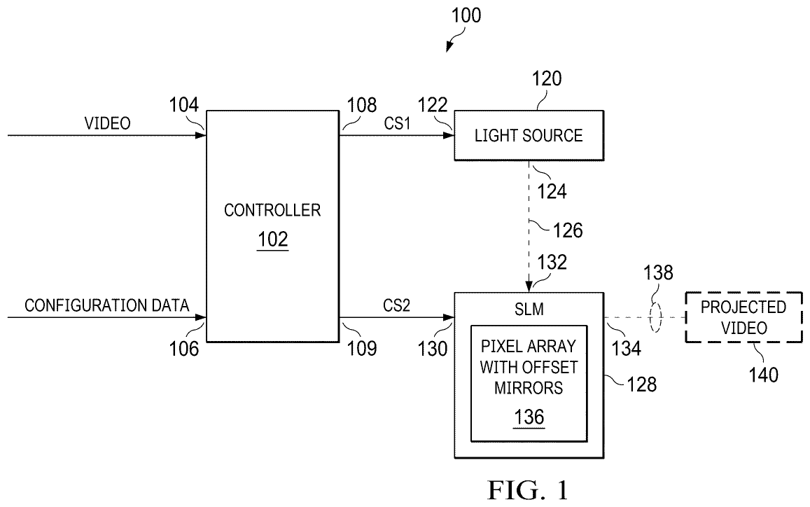

FIG. 1 is a block diagram of a system 100 in accordance with various examples. In some examples, system 100 is a projector, for example a traditional projector, an augmented reality (AR) display, a virtual reality (VR) display, a smart headlight, a heads-up display (HUD), an automotive ground projector, a light detection and ranging (LIDAR) unit, a lithography unit, a three-dimensional (3D) printer, a spectroscopy display, a 3D display, or another type of projector. The system 100 may also represent some or all of a display such as a DMD display.

As shown, system 100 includes a controller 102, a light source 120, an SLM 128, and a projection aperture 138. The controller 102 has a first terminal 104, a second terminal 106, a third terminal 108, and a fourth terminal 109. The light source 120 has an input 122 and an optical output 124. The SLM 128 has an input 130, an optical input 132, and an optical output 134. In the example of FIG. 1, the SLM 128 includes a pixel array 136 having pixels with offset mirrors as described herein. In different examples, the SLM 128 may perform spatial modulation of light using mechanical, electro-optical, thermo-optical, and/or magneto-optical control options.

In the example of FIG. 1, the controller 102 operates to: receive video data at the first terminal 104; receive configuration data at the second terminal 106; provide control signals CS1 at the third terminal 108 responsive to the video data and the configuration data; and provide control signal CS2 at the fourth terminal 109 responsive to the video and the configuration data. The light source 120 operates to: receive the control signals CS1 at the input 122; and generate light 126 at the optical output 124 responsive to the control signal CS1. In some examples, the light source 120 modulates the intensity, color, and/or timing of the light 126 at the optical output 124 responsive to the control signal CS1. The SLM 128 operates to: receive the control signals CS2 at the input 130; receive the light 126 at the optical input 132; and provide spatially-modulated light at the optical output 134 responsive to the light 126 and the control signals CS2. In some examples, the control signals CS2 include bit plane (BP) data and control signals to control light modulation options of the SLM 128. Without limitation, the control signals CS2 may be transferred to the SLM 128 using low-voltage differential signaling (LVDS). The spatially-modulated light from the SLM 128 results in projected video 140.

With the pixel array 136 and related offset mirrors, the reflectivity of MEMS device components of the SLM 128 relative to the projection aperture 138 is reduced when the MEMS devices are in an off-state. This reduction in reflectivity results in the projected video 140 having an improved contrast relative to an SLM having a pixel array without offset mirrors.

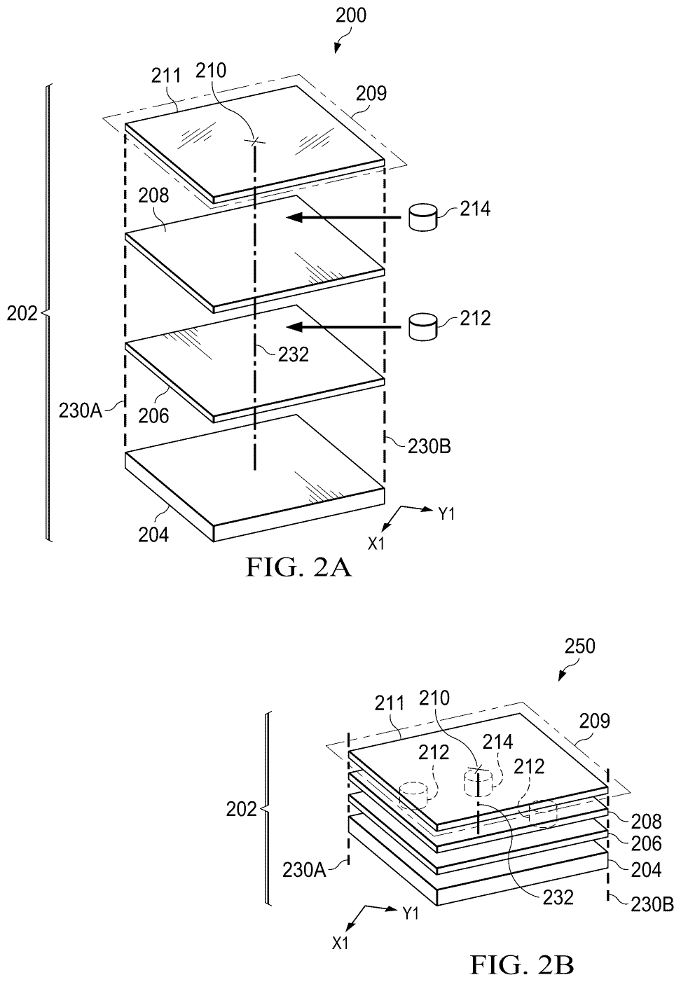

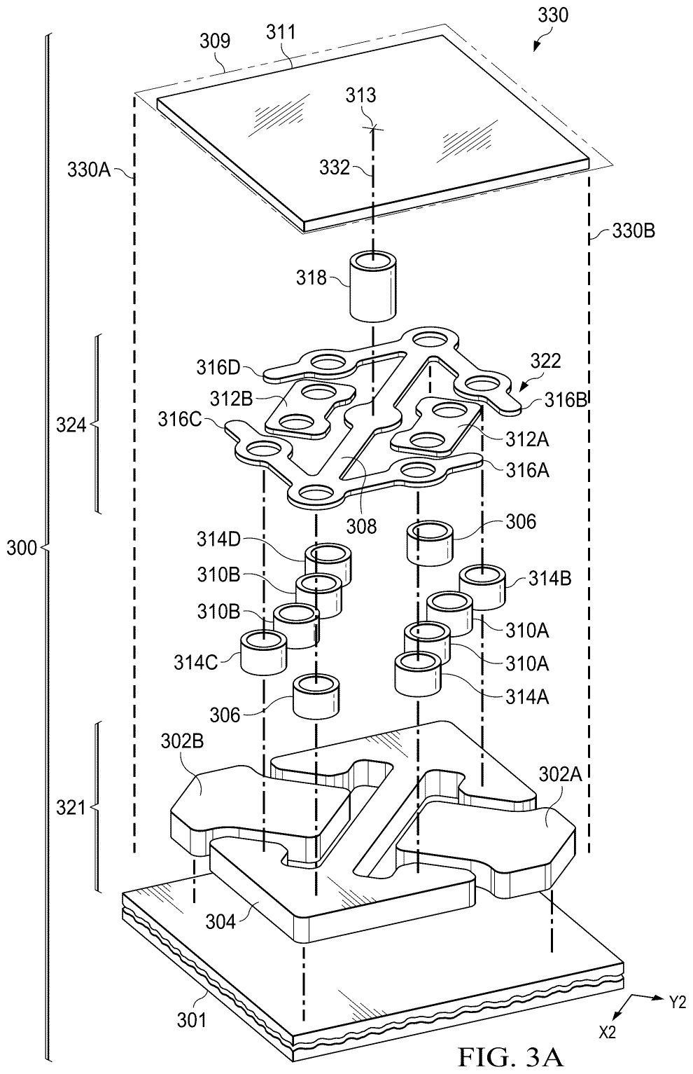

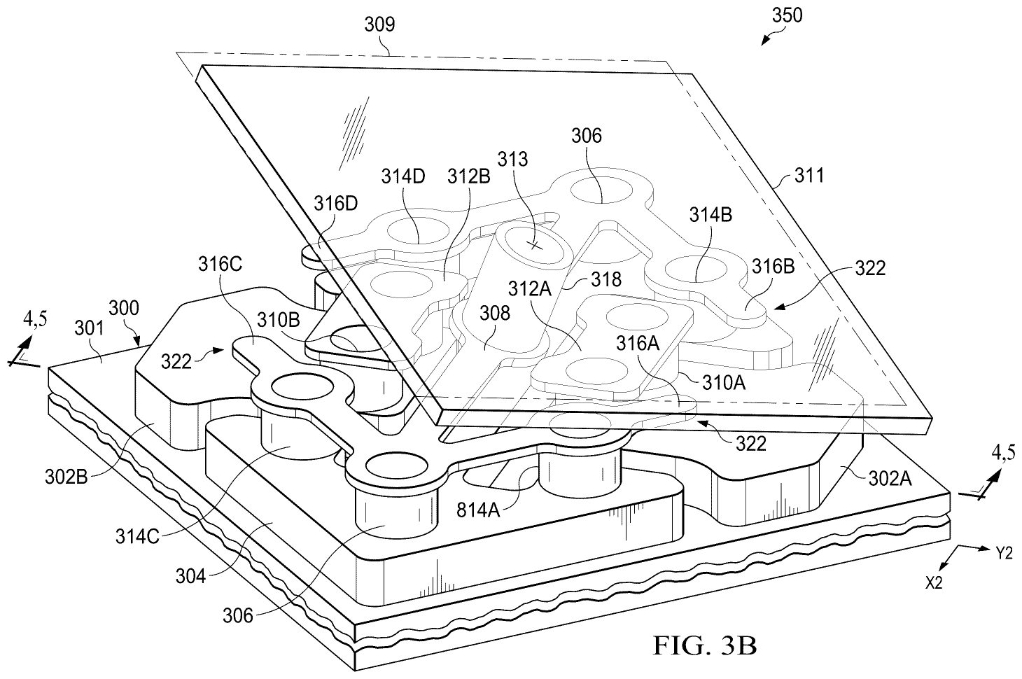

FIG. 2A is an exploded view 200 of a MEMS device 202 in accordance with various examples. The MEMS device 202 is an example of a pixel of the pixel array 136 of the SLM 128 in FIG. 1. In some examples, the MEMS device 202 is part of a dual spring tip pixel as in FIGS. 3A to 3E. In other examples, the MEMS device 202 is part of a cantilever hinge pixel as in FIG. 8.

In the example of FIG. 2A, the MEMS device 202 includes a base 204, an electrode layer 206, via(s) 212, a mechanical layer 208, via(s) 214, and an offset mirror 211. The base 204 includes memory cells (not shown) to control different states of the MEMS device 202 responsive to received data. In some examples, the electrode layer 206 includes first and second electrodes coupled to the base 204. In some examples, via(s) 212 may include electrode vias, spring tip vias, and/or hinge vias. In some examples, the mechanical layer 208 includes one or more hinges, raised electrodes, spring tips, and/or other components. In some examples, via(s) 214 may include a mirror via. In some examples, the via(s) 212 couple the mechanical layer 208 to the electrode layer 206. Additionally, or alternatively, the via(s) 214 may couple the mechanical layer 208 to the offset mirror 211.

In the example of FIGS. 2A and 2B, the offset mirror 211 is offset relative to a center position 209. In some examples, the center position 209 aligns a center point 210 of the center position 209 with a mirror via center (e.g., a center point of one of the via(s) 214), a layer center (e.g., a center point of the mechanical layer 208 and/or a center point of the electrode layer 206), and/or a center line 232 of MEMS device 20. The center line 232 of the MEMS device 202 may be aligned, for example, with a via center, a first layer center (e.g., a center point of the electrode layer 206) and/or a second layer center (e.g., a center point of the mechanical layer 208). As another option, the center position 209 is aligned with boundaries 230A and 230B of the MEMS device 202. The boundaries 230A and 230B are selected, for example, based on outer boundaries of the electrode layer 206 and/or the mechanical layer 208. In the example of FIGS. 2A and 2B, the offset mirror 211 is offset from the center position 209 in the Y1 direction to increase coverage of a target component relative to a projection aperture while the MEMS device 202 is in an off-state. In some examples, the target component is a mechanical layer component (e.g., a hinge, a spring tip, and/or a raised electrode).

FIG. 2B is a perspective view 250 of the MEMS device 202 of FIG. 1A in accordance with various examples. In the example of FIG. 2B, the MEMS device 202 includes the base 204, the electrode layer 206, the mechanical layer 208, and the offset mirror 211 together. In the example of FIG. 2B, the via(s) 212 couple the electrode layer 206 and the mechanical layer 208. Also, the via(s) 214 couple the mechanical layer 208 and the offset mirror 211. With the offset mirror 211 offset in the Y1 direction, exposure of a target component to the projection aperture 138 is reduced compared to a mirror having the center position 209.

Reducing reflections from a target component while the MEMS device 202 is in an off-state improves the contrast between on/off states of the MEMS device 202 relative to the projection aperture 138 (i.e., use of the offset mirror 211 results in a darker off-state of the MEMS device 202 as viewed from the projection aperture 138 compared to use of a mirror having the center position 209). With a mirror at the center position 209, the target component may be a mechanical layer component (e.g., a hinge, a spring tip, a raised electrode, etc.) that is reflective and at least partially exposed relative to the projection aperture 138 while the MEMS device 202 is in an off-state. Such exposure of the target component can result in some reflected light being directed towards the projection aperture 138 while the MEMS device 202 is in the off-state. With the offset mirror 211 offset in the Y1 direction instead of a mirror in the center position 209, the exposure of the target component relative to the projection aperture while the MEMS device 202 is in the off-state is reduced or eliminated. This reduction in exposure of the target component while the MEMS device 202 results in a darker off-state for the MEMS device, improving overall contrast between the on-state and the off-state of the MEMS device 202.

In the example of FIGS. 2A and 2B, the MEMS device 202 is oriented based on an X1 direction and a Y1 direction. With the orientation represented in FIGS. 2A and 2B, the offset mirror 211 is offset towards the Y1 direction relative to the center position 209. In other examples, depending on the layout of mechanical layer components, the offset mirror 211 may be offset towards a −Y1 direction, the X1 direction, the −X1 direction, or a combination of directions (e.g., an X1 and Y1 direction, an X1 and −Y1 direction, a −X1 and Y1 direction, or a −X1 and −Y1 direction).

FIGS. 3A and 3B are different views 330 and 350 of an example MEMS device 300. The MEMS device 300 is an example of a dual spring tip pixel of the pixel array 136 of the SLM 128 in FIG. 1, or the MEMS device 202 in FIGS. 2A and 2B. FIG. 3A is an exploded view 330 of the MEMS device 300. FIG. 3B is a perspective view 350 of the MEMS device 300. In the example of FIG. 3A, the MEMS device 300 includes a base 301, a first address electrode 302A, a second address electrode 302B, a bias electrode 304, spring tip vias 314A, 314B, 314C, and 314D, first electrode vias 310A, second electrode vias 310B, hinge vias 306, a torsion hinge 308, spring tips 316A to 316D, a first raised electrode 312A, a second raised electrode 312B, a mirror via 318, and an offset mirror 311.

In the example of FIG. 3A, the base 301 is an example of the base 204 in FIGS. 2A and 2B. The first address electrode 302A, the second address electrode 302B, and the bias electrode 304 are example components of an electrode layer 321. The electrode layer 321 is an example of the electrode layer 206 in FIGS. 2A and 2B. The spring tip vias 314A, 314B, 314C, and 314D, the first electrode vias 310A, the second electrode vias 310B, and the hinge vias 306 are examples of the via(s) 212 in FIGS. 2A and 2B. The torsion hinge 308, the spring tips 316A to 316D, the first raised electrode 312A, and the second raised electrode 312B are example components of a mechanical layer 324. The mechanical layer 324 is an example of the mechanical layer 208 in FIGS. 2A and 2B. The mirror via 318 is an example of the via(s) 214 in FIGS. 2A and 2B. The offset mirror 311 is an example of the offset mirror 211 in FIGS. 2A and 2B.

In the example of FIGS. 3A and 3B, the offset mirror 311 is offset relative to a center position 309. In some examples, the center position 309 aligns a center point 313 of the center position 309 with a mirror via center (e.g., a center point of the mirror via 318), a layer center (e.g., a center point of the mechanical layer 324 and/or a center point of the electrode layer 321), and/or a center line 332 of MEMS device 300. The center line 332 of the MEMS device 300 may be aligned, for example, with a via center, a first layer center (e.g., a center point of the electrode layer 321) and/or a second layer center (e.g., a center point of the mechanical layer 324). As another option, the center position 309 is aligned with boundaries 330A and 330B of the MEMS device 300. The boundaries 330A and 330B are selected, for example, based on outer boundaries of the electrode layer 321 and/or the mechanical layer 324. In the example of FIGS. 3A and 3B, the offset mirror 311 is offset from the center position 309 in the Y2 direction to increase coverage of a target component relative to a projection aperture while the MEMS device 300 is in an off-state. In some examples, the target component is a mechanical layer component (e.g., the torsion hinge 308, one or more of the spring tips 316A to 316D, the first raised electrode 312A, and the second raised electrode 312B).

In the example of FIG. 3B, the position of the offset mirror 311 is tilted towards the spring tips 316A and 316B, which may be an on position for the offset mirror 311. In an example SLM, the position of the offset mirror 311 switches between different tilted positions (e.g., an on position in which the offset mirror 311 contacts spring tips 316A and 316B, and an off position in which the offset mirror 311 contacts the spring tips 316C and 316C) responsive to: received data; control voltages applied to the first address electrode 302A, the second address electrode 302B, and the bias electrode 304 responsive to received data; and movement of the torsion hinge 308 and offset mirror 311 responsive to application of the control voltages.

In the example of FIG. 3B, the offset mirror 311 is in a first position, in which the offset mirror 311 contacts the spring tips 316A and 316B at contact points 322 responsive to control voltages applied to the first address electrode 302A, the second address electrode 302B, and the bias electrode 304. To change the position of the offset mirror 311 to another position (e.g., the offset mirror 311 may contact the spring tips 316C and 316D), updated control voltages are applied to the first address electrode 302A, the second address electrode 302B, and/or the bias electrode 304.

In the example of FIGS. 3A and 3B, the MEMS device 300 is oriented based on an X2 direction and a Y2 direction. With the orientation represented in FIGS. 3A and 3B, the offset mirror 311 is offset towards the Y2 direction. In other examples, the offset mirror 311 may be offset towards a −Y2 direction, the X2 direction, the −X2 direction, or a combination of directions (e.g., an X2 and Y2 direction, an X2 and −Y2 direction, a −X2 and Y2 direction, or a- X2 and −Y2 direction).

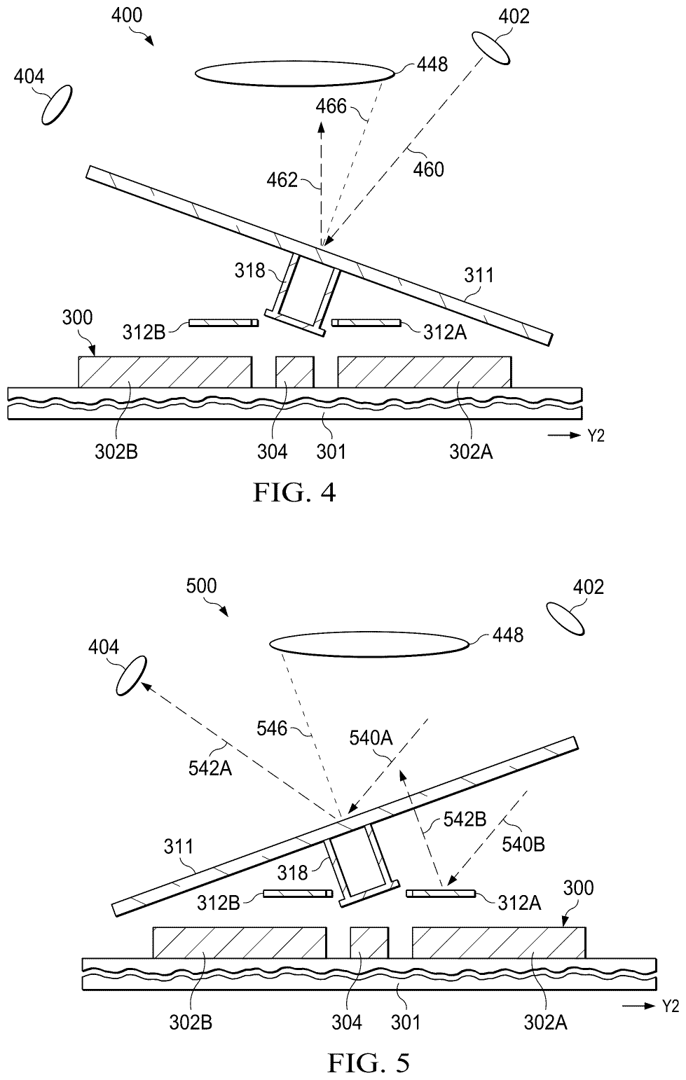

FIG. 4 is a cross-sectional view 400 of the MEMS device 300 of FIG. 3B in an on-state. In the cross-sectional view 400 of FIG. 4, the base 301, the first address electrode 302A, the second address electrode 302B, the bias electrode 304, the first raised electrode 312A, the second raised electrode 312B, the mirror via 318, and the offset mirror 311 of the MEMS device 300 are represented. Also represented in FIG. 4 is a projection aperture 448, a light source 402, a light sink 404, incoming light 460 (e.g., from the light source 402, outgoing light 462, and a mirror normal direction 466. The light source 402 is an example of the light source 120 in FIG. 1. The projection aperture 448 is an example of the projection aperture 138 in FIG. 1. The mirror normal direction 466 is perpendicular to the surface of the offset mirror 311 in the on position.

When the MEMS device 300 is in the on-state as in the example of FIG. 4, the offset mirror 311 is in an on position. With the offset mirror 311 in the on position, the outgoing light 462, resulting from the incoming light 460 reflecting from the surface of the offset mirror 311, is directed towards the projection aperture 448 and not the light sink 404. The offset mirror 311 in the on position does not significantly alter the amount of the outgoing light 462 directed to the projection aperture 448 relative to a mirror having a center position (see e.g., the center position 209 in FIG. 2, or the center position 309 in FIG. 3). However, in an off position, the offset mirror 311 reduces the amount of stray light (e.g., light remaining after the on-state due to reflections or other design issues) directed to the projection aperture 448.

FIG. 5 is a cross-sectional view 500 of the MEMS device 300 of FIG. 3B in an off-state. In the cross-sectional view 500 of FIG. 5, the base 301, the first address electrode 302A, the second address electrode 302B, the bias electrode 304, the first raised electrode 312A, the second raised electrode 312B, the mirror via 318, and the offset mirror 311 of the MEMS device 300 are represented. Also represented in FIG. 5 is the projection aperture 448, the light source 402, the light sink 404, first stray light 540A (e.g., stray light remaining the on-state of FIG. 4), first outgoing light 542A, second stray light 540B (e.g., stray light remaining the on-state of FIG. 4), second outgoing light 542B, and a mirror normal direction 546. The mirror normal direction 546 is perpendicular to the surface of the offset mirror 311 in the off position.

When the MEMS device 300 is in the off-state, the offset mirror 311 is in the off position. With the offset mirror 311 in the off position, the first outgoing light 542A, resulting from the first stray light 540A reflecting from the surface of the offset mirror 311, is directed away from the projection aperture 448 to the light sink 404. However, the second outgoing light 542B, resulting from the second stray light 540B reflecting from surfaces below the offset mirror 311 (e.g., the first raised electrode 312A, other mechanical layer components, and/or electrode layer components), is directed towards the projection aperture 448. The result of the second outgoing light 542B being directed to the projection aperture 448 while the MEMS device 300 is in the off-state is that the contrast (the difference between on-state lighting versus off-state lighting of the MEMS device 300) is reduced. With the offset mirror 311, the amount of second outgoing light 542B directed to the projection aperture 448 is reduced compared to when a non-offset mirror is used. This is because the offset mirror 311 reduces exposure of a reflective target component (e.g., the torsion hinge 308, the spring tips 316A to 316D, the first raised electrode 312A, and/or the second raised electrode 312B) to the projection aperture 448. In the example of FIG. 5, the second outgoing light 542B is represented as being reflected from the first raised electrode 312A. In other examples, outgoing light directed to the projection aperture 448 is due to stray light being reflected from a spring tip (e.g., one or more of the spring tips 316A to 316D).

In the example of FIG. 5, the offset mirror 311 is offset in the Y2 direction to cover more of a target mechanical layer component (e.g., the first raised electrode 312A, the second raised electrode 312B, a torsion hinge 308 as in FIGS. 3A and 3B, and/or springs tips 316A, 316B, 316C, and/or 316D), a target electrode layer component (e.g., the first address electrode 302A, the second address electrode 302B, and/or the bias electrode 304), and/or a via (e.g., the mirror via 318, the hinge vias 306, the spring tip vias 314A, 314B, 314C, and/or 314D, the first electrode vias 310A and/or second electrode vias 310B).

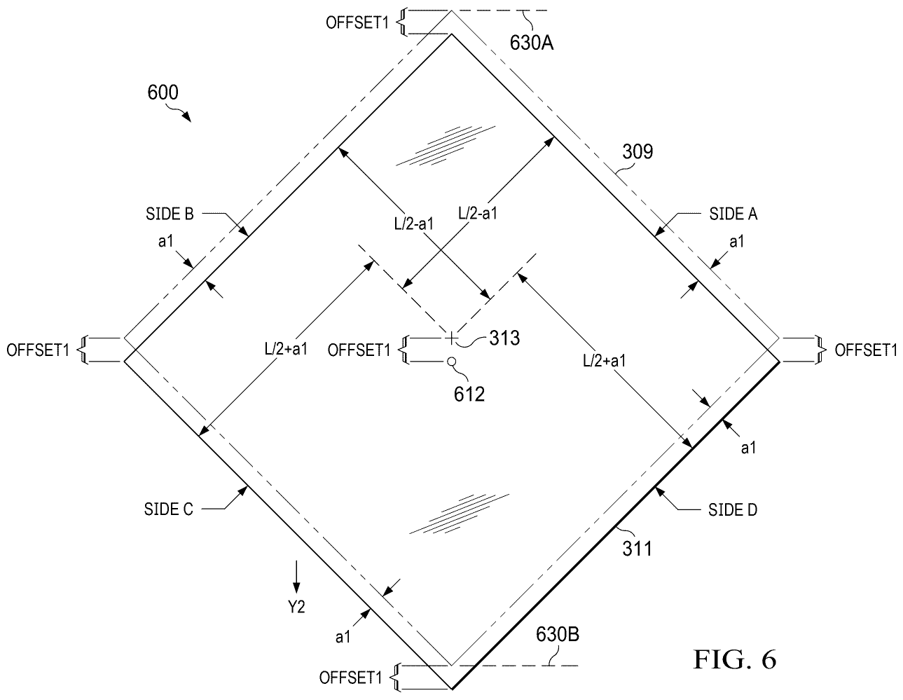

FIG. 6 is a top view 600 of the offset mirror 311 of the MEMS device 300 of FIG. 3B relative to the center position 309. In the example of FIG. 6, the center position 309 has the center point 313 and sides A, B, C, and D. The offset mirror 311 also has a center point 612 and sides A, B, C, and D. In some examples, the center position 309 aligns the center point 313 with a mirror via center (e.g., a center point of the mirror via 318 in FIGS. 3A and 3B) and/or a layer center (e.g., a center point of the mechanical layer 324 in FIG. 3A and/or a center point of the electrode layer 321 in FIG. 3A). As another option, the center position 309 is aligned with boundaries 630A and 630B in FIG. 6. The boundaries 630A and 630B are selected, for example, based on outer boundaries of the electrode layer 321 of the MEMS device 300 and/or of the mechanical layer 324 of the MEMS device 300. In the example of FIG. 6, the offset mirror 311 is offset from the center position 309 or the center point 313 of the center position 309 in the Y2 direction by a spacing (OFFSET1). OFFSET1 is also the difference between the center point 313 of the center position 309 and the center point 612 of the offset mirror 311. With OFFSET1, side A of center position 309 is offset from side A of the offset mirror 311 by spacing a1, side B of center position 309 is offset from side B of the offset mirror 311 by spacing a1, side C of center position 309 is offset from side C of the offset mirror 311 by spacing a1, and side D of center position 309 is offset from side D of the offset mirror 311 by spacing a1. Assuming a square shape for the offset mirror 311 and a perpendicular intersection, the distance from the center point 313 of the center position 309 to side A of the offset mirror 311 is L/2−a1, where L is the length of each side of the offset mirror 311. The distance from the center point 313 of the center position 309 to a perpendicular intersection of side B of the offset mirror 311 is also L/2−a1. The distance from the center point 313 of the center position 309 to a perpendicular intersection of side C of the offset mirror 311 is also L/2+a1. The distance from the center point 313 of the center position 309 to a perpendicular intersection of side D of the offset mirror 311 is also L/2+a1. In the example of FIG. 6, OFFSET1=√2̅*̅a̅1̅²̅. . .

With OFFSET1 in the Y2 direction and the related spacings a1, the offset mirror 311 improves coverage of a target mechanical layer component (e.g., the first raised electrode 312A, the second raised electrode 312B, a torsion hinge 308 as in FIGS. 3A and 3B, and/or springs tips 316A, 316B, 316C, and/or 316D), a target electrode layer component (e.g., the first address electrode 302A, the second address electrode 302B, and/or the bias electrode 304), and/or a via (e.g., the mirror via 318, the hinge vias 306, the spring tip vias 314A, 314B, 314C, and/or 314D, first electrode vias 310A and/or second electrode vias 310B) relative to a projection aperture. In some examples, OFFSET1 in the Y2 direction is approximately 0.212 μm and the spacing a1 is approximately 0.15 μm for a 9.0 μm pixel size. In this first example, OFFSET1 is approximately 2.35% of the pixel size. In another example, OFFSET1 in the Y2 direction is approximately 0.106 micrometers and the spacing a1 is approximately 0.075 micrometers for a 9.0 μm pixel size. In this second example, OFFSET1 is approximately 1.18% of the pixel size. In different examples, the offset, the spacing a1, and/or the pixel size may vary. Example pixel sizes may range from 16 μm pixels down to 2.7 μm pixels or smaller.

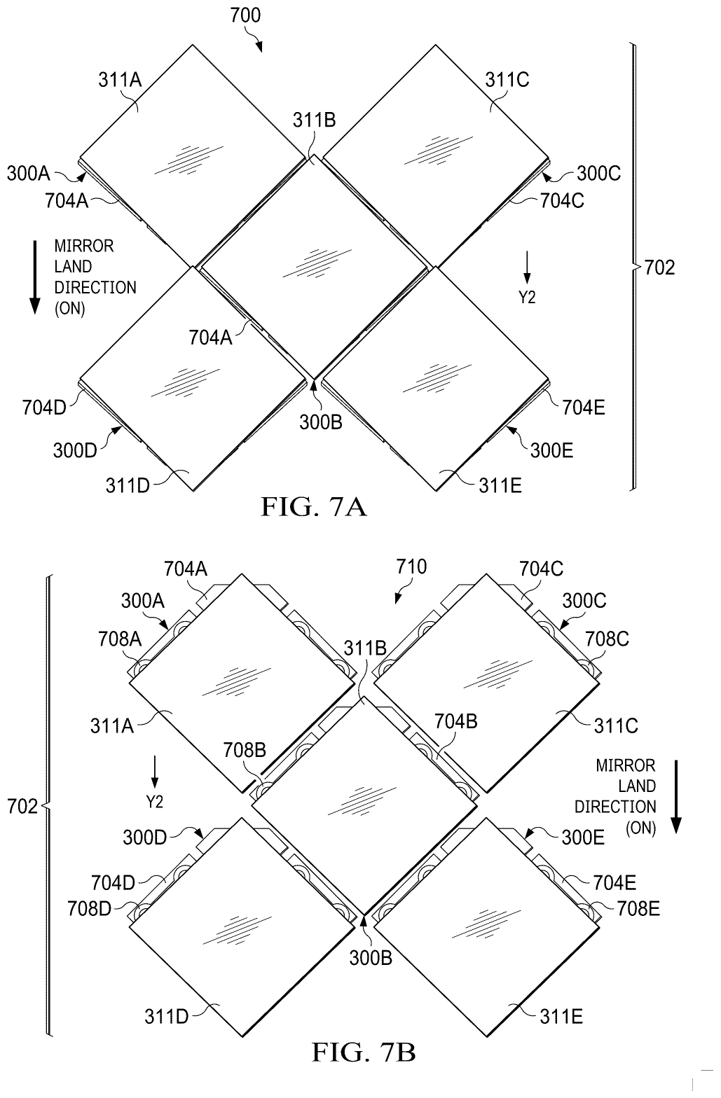

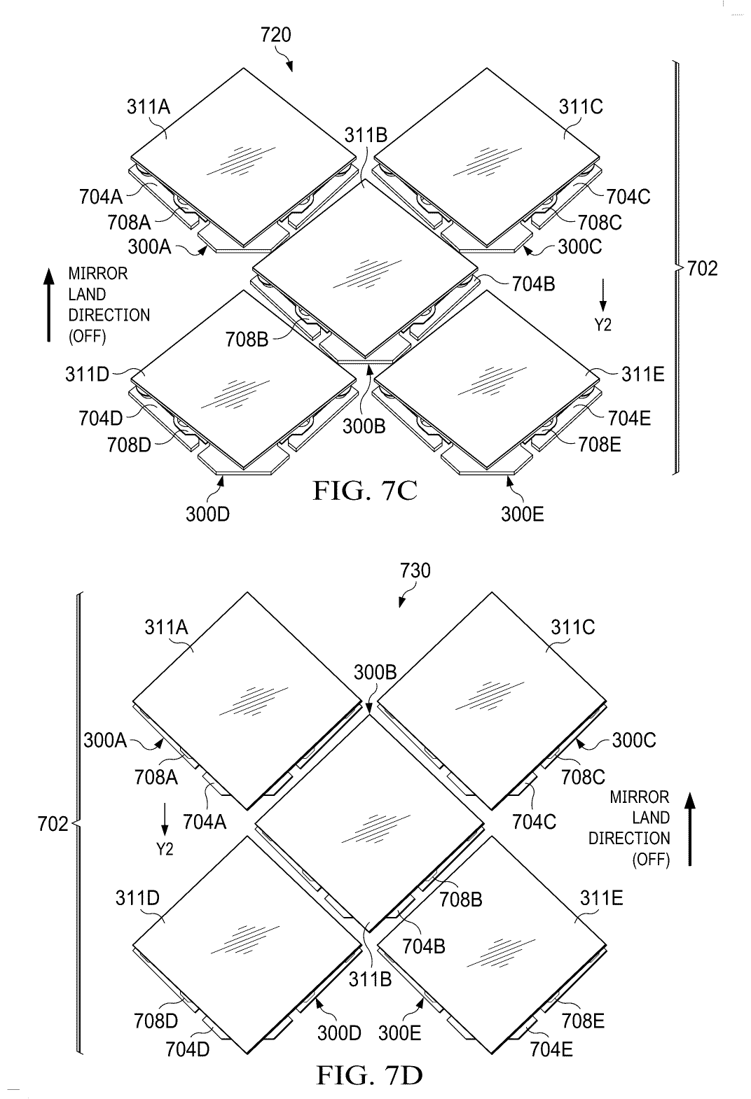

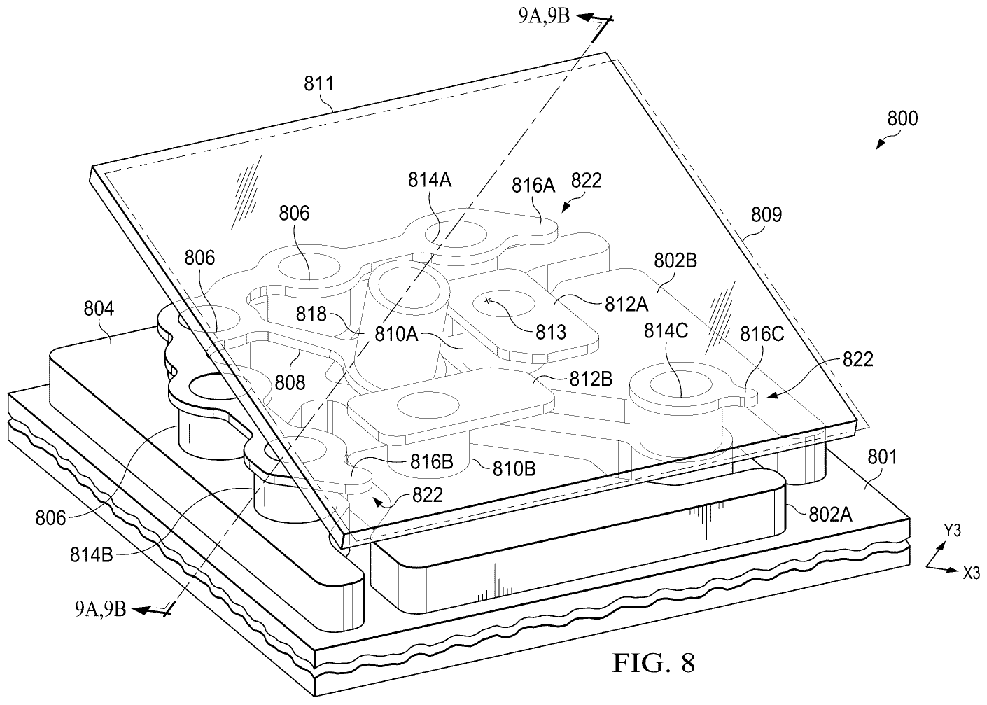

FIGS. 7A to 7D are different views 700, 710, 720, and 730 of a pixel array 702 based on MEMS devices 300A to 300E with respective offset mirrors 311A to 311E. Each of the MEMS devices 300A to 300E is an example of the MEMS device 300 in FIGS. 3A, 3B, 4, and 5. Each of the respective offset mirrors 311A to 311E is an example of the offset mirror 311 in FIGS. 3A, 3B, 4, 5, and 6. In FIGS. 7A to 7D, the offset mirrors 311A to 311E are offset in the Y2 direction relative to a center position (e.g., the center position 309 in FIG. 6).

FIG. 7A is an incoming light angle view 700 of part of the pixel array 702 with the offset mirrors 311A to 311E in an on position (the mirror land direction or tilt for the on position is in the Y2 or down direction in FIG. 7A). In the example of FIG. 7A, the offset mirrors 311A to 311E, and electrode layer component portions 704A to 704E of the respective MEMS devices 300A to 300E are represented. In FIGS. 7A to 7D, the offset mirrors 311A to 311E are offset relative to other MEMS device layers including respective electrode layers (e.g., each respective electrode layer represented by the electrode layer 321 in FIG. 3A) and respective mechanical layers (e.g., each respective mechanical layer represented by the mechanical layer 324 in FIGS. 3A). Each of the electrode layer component portions 704A to 704E may be part of a first address electrode (e.g., the first address electrode 302A in FIGS. 3A, 3B, 4, and 5), part of a second address electrode (e.g., the second address electrode 302B in FIGS. 3A, 3B, 4, and 5), or part of a bias electrode (e.g., the bias electrode 304 in FIGS. 3A, 3B, 4, and 5).

FIG. 7B is a projection aperture view 710 of the pixel array 702 with the offset mirrors 311A to 311E in an on position (the mirror land direction or tilt for the on position is in the Y2 or down direction in FIG. 7B). In the example of FIG. 7B, the offset mirrors 311A to 311E, the electrode layer component portions 704A to 704E, and mechanical layer component portions 708A to 708E of the respective MEMS devices 300A to 300E are represented. Each of the mechanical layer component portions 708A to 708E may be part of a torsion hinge (e.g., the torsion hinge 308 in FIGS. 3A, 3B, 4, and 5), part of a spring tip (e.g., the spring tips 316A to 316D in FIGS. 3A and 3B), part of a first raised electrode (e.g., the first raised electrode 312A in FIGS. 3A, 3B, 4, and 5), or part of a second raised electrode (e.g., the second raised electrode 312B in FIGS. 3A, 3B, 4, and 5).

FIG. 7C is an incoming light angle view 720 of the pixel array 702 with the offset mirrors 311A to 311E in an off position (the mirror land direction or tilt for the off position is in the −Y2 or up direction in FIG. 7C). In the example of FIG. 7C, the offset mirrors 311A to 311E, the electrode layer component portions 704A to 704E, and the mechanical layer component portions 708A to 708E of the respective MEMS devices 300A to 300E are represented.

FIG. 7D is a projection aperture view 730 of the pixel array 702 with the offset mirrors 311A to 311E in the off position (the mirror land direction or tilt for the off position is in the −Y2 or up direction in FIG. 7D). In the example of FIG. 7C, the offset mirrors 311A to 311E, the electrode layer component portions 704A to 704E, and the mechanical layer component portions 708A to 708E of the respective MEMS devices 300A to 300E are represented.

In the incoming light angle view 700 of FIG. 7A, with the offset mirrors 311A to 311E in the on position, most MEMS device components below the offset mirrors 311A to 311E are not visible except some electrode layer component portions such as the electrode layer component portions 704A to 704E. In the projection aperture view 710 of FIG. 7B, with the offset mirrors 311A to 311E in the on position, most MEMS device components below the offset mirrors 311A to 311E are not visible except some electrode layer component portions such as the electrode layer component portions 704A to 704E and some mechanical layer component portions such as the mechanical layer component portions 708A to 708E. In the incoming light angle view 720 of FIG. 7C, with the offset mirrors 311A to 311E in the off position, most MEMS device components below the offset mirrors 311A to 311E are not visible except some electrode layer component portions such as the electrode layer component portions 704A to 704E and some mechanical layer component portions such as the mechanical layer component portions 708A to 708E. Although more of the electrode layer component portions 704A to 704E and more of the mechanical layer component portions 708A to 708E are visible in the incoming light angle view 720 of FIG. 7C, the incoming light view 720 does not significantly affect the amount of stray light directed to a projection aperture. Exposure of electrode layer component portions 704A to 704E and/or the mechanical layer component portions 708A to 708E relative to a projection aperture is more relevant than exposure from an incoming light view. In the projection aperture view 730 of FIG. 7D, with the offset mirrors 311A to 311E in the off position, most MEMS device components below the offset mirrors 311A to 311E are not visible except some electrode layer component portions such as the electrode layer component portions 704A to 704E and some mechanical layer component portions such as the mechanical layer component portions 708A to 708E. Compared to mirrors aligned with center positions (e.g., the center position 209 in FIGS. 2A and 2B, or the center position 309 in FIGS. 3A, 3B, and 6), the offset mirrors 311A to 311E cover more electrode layer component portions (e.g., more of the electrode layer component portions 704A to 704E) and/or mechanical layer component portions (e.g., more of the mechanical layer component portions 708A to 708E) relative to a projection aperture, which improves contrast.

Compared to mirrors in a centered position, the offset mirrors 311A to 311E in FIGS. 7A to 7D cover more mechanical layer component portions such as the mechanical layer component portions 708A to 708E. Compared to mirrors in a centered position, the offset mirrors 311A to 311E in FIGS. 7A to 7D may also cover more electrode layer component portions such as the electrode layer component portions 704A to 704E. To improve contrast of a display or projector, increased coverage of mechanical layer components for the projection aperture view 730 of FIG. 7D has highest priority. This is because scattered light due to visibility of mechanical layer components in the projection aperture view 730 reaches the aperture (e.g., the projection aperture 138). While full coverage of mechanical layer components for the projection aperture view 730 is optimal, any coverage improvement of mechanical layer components (relative to centered mirrors) can provide a contrast improvement.

In some examples, electrode layer components are treated with a non-reflective coating, while mechanical layer components (e.g., the torsion hinge 308, the spring tips 316A to 316D, the first raised electrode 312A, and/or the second raised electrode 312B) are untreated. In some examples, treating mechanical layer components with a non-reflective coating is avoided to ensure consistent movement of the mechanical layer components. In the described examples, the reflectivity of untreated mechanical layer components may result is some extraneous reflected light being directed to a projection aperture. In the described examples, the amount of extraneous reflected light due to mechanical layer components is reduced, at least in a projection aperture view such as the projection aperture view 730, using offset mirrors (e.g., the offset mirrors 311A to 311E).

FIG. 8 is a perspective view of a MEMS device 800 in accordance with various examples. The MEMS device 800 is an example of a cantilever hinge pixel of the pixel array 136 of the SLM 128 in FIG. 1, or the MEMS device 202 in FIGS. 2A and 2B. In the example of FIG. 8, the MEMS device 800 includes a base 801, a first address electrode 802A, a second address electrode 802B, a bias electrode 804, spring tip vias 814A, 814B, and 814C, a first electrode via 810A, a second electrode via 810B, hinge vias 806, a cantilever hinge 808, spring tips 816A to 816C, a first raised electrode 812A, a second raised electrode 812B, a mirror via 818, and an offset mirror 811.

In the example of FIG. 8, the base 801 is an example of the base 204 in FIGS. 2A and 2B. The first address electrode 802A, the second address electrode 802B, and the bias electrode 804 are example components of an electrode layer such as the electrode layer 206 in FIGS. 2A and 2B. The spring tip vias 814A, 814B, and 814C, the first electrode via 810A, the second electrode via 810B, and the hinge vias 806 are example vias such as the via(s) 212 in FIGS. 2A and 2B. The cantilever hinge 808, the spring tips 816A to 816C, the first raised electrode 812A, and the second raised electrode 812B are example components of a mechanical layer such as the mechanical layer 208 in FIGS. 2A and 2B. The mirror via 818 is an example of via(s) 214 in FIGS. 2A and 2B. The offset mirror 811 is an example of the offset mirror 211 in FIGS. 2A and 2B.

In the example of FIG. 8, the position of the offset mirror 811 is tilted towards the spring tips 816B and 816C, which may be an on position for the offset mirror 811. In an example SLM, the position of the offset mirror 811 switches between different tilted positions (e.g., an on position in which the offset mirror 811 contacts spring tips 816B and 816C, and an off position in which the offset mirror 811 contacts the spring tips 816A and 816C) responsive to: received data; control voltages applied to the first address electrode 802A, the second address electrode 802B, and the bias electrode 804 responsive to received data; and movement of the cantilever hinge 808 and offset mirror 811 responsive to application of the control voltages.

In the example of FIG. 8, the offset mirror 811 is in a first position, in which the offset mirror 811 contacts the spring tips 816B and 816C at contact points 822 responsive to control voltages applied to the first address electrode 802A, the second address electrode 802B, and the bias electrode 804. To change the position of the offset mirror 811 to another position (e.g., the offset mirror 811 may contact the spring tips 816A and 816C), updated control voltages are applied to the first address electrode 802A, the second address electrode 802B, and/or the bias electrode 804. In the example of FIGS. 8, the MEMS device 800 is oriented based on an X3 direction and a Y3 direction. Also, the offset mirror 811 is offset relative to a center position 809. In some examples, the center position 809 aligns a center point 813 of the center position 809 with a mirror via center (e.g., a center point of the mirror via 818), a layer center (e.g., a center point of the mechanical layer of the MEMS device 800 and/or a center point of the electrode layer of the MEMS device 800), and/or a center line 332 of MEMS device 300. As another option, the center position 309 is aligned with boundaries of the MEMS device 800. Such boundaries may be selected, for example, based on outer boundaries of the electrode layer and/or the mechanical layer of the MEMS device 800. In the example of FIG. 8, the offset mirror 811 is offset from the center position 809 in the X3 and Y3 directions to increase coverage of a target component relative to a projection aperture while the MEMS device 800 is in an off-state. In some examples, the target component is a mechanical layer component (e.g., the cantilever hinge 808, one or more of the spring tips 816A to 816C, the first raised electrode 812A, and the second raised electrode 812B). With the orientation represented in FIG. 8, the offset mirror 811 is offset towards the−X3 and−Y3 directions. In other examples, the offset mirror 311 may be offset towards a X3 direction, a −X3 direction, a Y3 direction, a −Y3 direction, or a combination of directions (e.g., an X3 and Y3 direction, an X3 and −Y3 direction, or a −X3 and Y3 direction).

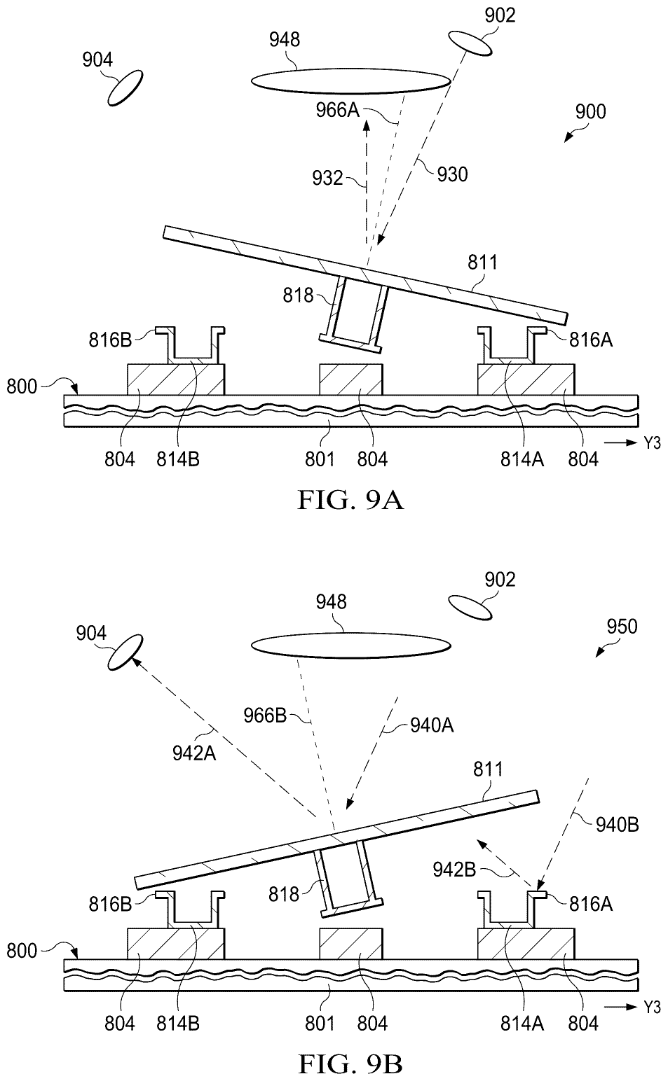

FIG. 9A is a cross-sectional view 900 of the MEMS device 800 of FIG. 8 in an on-state. In the cross-sectional view 900 of FIG. 9A, the base 801, the bias electrode 804, the spring tips 816A and 816B, the mirror via 818, and the offset mirror 811 are represented. Also represented in FIG. 9A is a projection aperture 948, a light source 902, a light sink 904, incoming light 930 (e.g., from the light source 902), outgoing light 932, and a first mirror normal direction 966A. The light source 902 is an example of the light source 120 in FIG. 1. The projection aperture 948 is an example of the projection aperture 138 in FIG. 1. The first mirror normal direction 966A is perpendicular to the surface of the offset mirror 811 in the on position. When the MEMS device 800 is in the on-state as in the example of FIG. 9A, the offset mirror 811 is in an on position.

With the offset mirror in the on position, the outgoing light 932, resulting from the incoming light 930 reflecting from the surface of the offset mirror 811, is directed towards the projection aperture 948 and not the light sink 904. The offset mirror 811 in the on position does not significantly alter the amount of the outgoing light 932 directed to the projection aperture 948 relative to a mirror having a center position (see e.g., the center position 809 in FIG. 8). However, in an off position, the offset mirror 811 reduces the amount of stray light (e.g., light remaining after the on-state due to reflections or other design issues) directed to the projection aperture 948.

FIG. 9B is a cross-sectional view 950 of the MEMS device 800 of FIG. 8 in an off-state. In the cross-sectional view 950 of FIG. 9B, the base 801, the bias electrode 804, the spring tips 816A and 816B, the mirror via 818, and the offset mirror 811 of the MEMS device 800 are represented. Also represented in FIG. 9B is the projection aperture 948, the light source 902, the light sink 904, first stray light 940A (e.g., stray light remaining the on-state of FIG. 9A), first outgoing light 942A, second stray light 940B (e.g., stray light remaining the on-state of FIG. 9A), second outgoing light 942B, and a second mirror normal direction 966B. The second mirror normal direction 966B is perpendicular to the surface of the offset mirror 811 in the off position. When the MEMS device 800 is in the off-state, the offset mirror 811 is in the off position. With the offset mirror 811 in the off position, the first outgoing light 942A, resulting from the first stray light 940A reflecting from the surface of the offset mirror 811, is directed away from the projection aperture 948 to the light sink 904. However, the second outgoing light 942B, resulting from the second stray light 940B reflecting from surfaces below the offset mirror 811 (e.g., the spring tips 816A, other mechanical layer components, and/or electrode layer components), is directed towards the projection aperture 948. The result of the second outgoing light 942B being directed to the projection aperture 948 while the MEMS device 800 is in the off-state is that the contrast (the difference between on-state lighting versus off-state lighting of the MEMS device 800) is reduced. With the offset mirror 811, the amount of second outgoing light 942B directed to the projection aperture 948 is reduced compared to when a non-offset mirror is used. This is because the offset mirror 811 reduces exposure of a reflective target component (e.g., the cantilever hinge 808, the spring tips 816A to 816C, the first raised electrode 812A, and/or the second raised electrode 812B) to the projection aperture 948. In the example of FIG. 9B, the second outgoing light 942B is represented as being reflected from the spring tip 816A. In other examples, outgoing light directed to the projection aperture 448 is due to stray light being reflected from another spring tip (e.g., the spring tip 816B, the spring tip 816C), a raised electrode (e.g., the first raised electrode 812A or the second raised electrode 812B), and/or the cantilever hinge 808.

In the example of FIG. 9B, the offset mirror 811 is offset in the −X3 direction to cover more of a target mechanical layer component (e.g., the spring tips 816A to 816C, first raised electrode 812A, the second raised electrode 812B, or the cantilever hinge 808 as in FIG. 8), a target electrode layer component (e.g., the first address electrode 802A, the second address electrode 802B, and/or the bias electrode 804), and/or a via (e.g., the mirror via 818, the hinge vias 806, the spring tip vias 314A, 314B, and 314C, first electrode via 810A and/or the second electrode via 810B).

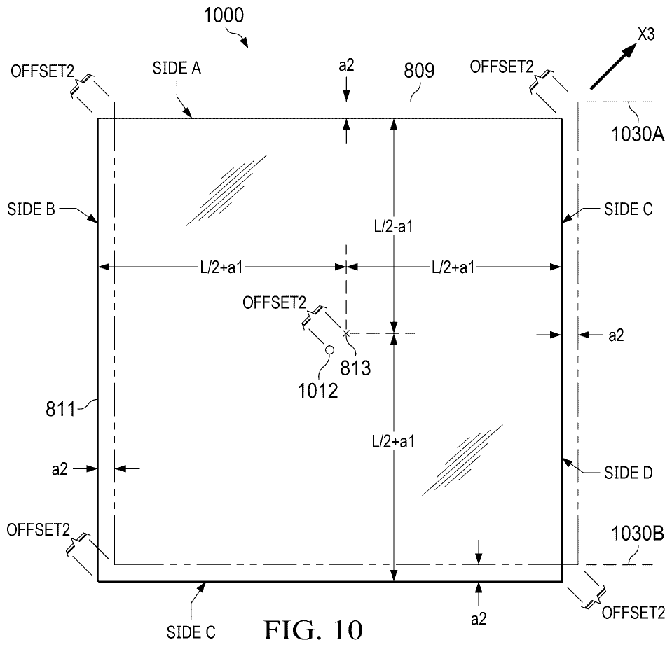

FIG. 10 is a top view 1000 of the offset mirror 811 of the MEMS device 800 of FIG. 3B relative to the center position 809. In the example of FIG. 10, the center position 809 has the center point 813 and sides A, B, C, and D. The offset mirror 811 also has a center point 1012 and sides A, B, C, and D. In some examples, the center position 809 aligns the center point 813 with a mirror via center (e.g., a center point of the mirror via 818 in FIG. 8) and/or a layer center (e.g., a center point of the mechanical layer of the MEMS device 800 in FIG. 8 and/or a center point of the electrode layer of the MEMS device 800 in FIG. 8). As another option, the center position 809 is aligned with boundaries 1030A and 1030B in FIG. 10. The boundaries 1030A and 1030B are selected, for example, based on outer boundaries of the electrode layer of the MEMS device 800 in FIG. 8 and/or of the mechanical layer of the MEMS device 800 in FIG. 8. In the example of FIG. 10, the offset mirror 811 is offset from the center position 809 or the center point 813 of the center position 809 in the −X3 direction by an offset (OFFSET2). OFFSET2 is also the difference between the center point 813 of the center position 809 and the center point 1012 of the offset mirror 811. With OFFSET2, side A of center position 809 is offset from side A of the offset mirror 811 by a2, side B of center position 809 is offset from side B of the offset mirror 811 by a2, side C of center position 809 is offset from side C of the offset mirror 811 by a2, and side D of center position 809 is offset from side D of the offset mirror 811 by a2. Assuming a square shape for the offset mirror 811 and a perpendicular intersection, the distance from the center point 813 of the center position 809 to side A of the offset mirror 311 is L/2−a2, where L is the length of each side of the offset mirror 811. The distance from the center point 813 of the center position 809 to a perpendicular intersection of side B of the offset mirror 311 is L/2+a2. The distance from the center point 813 of the center position 809 to a perpendicular intersection of side C of the offset mirror 811 is also L/2+a2. The distance from the center point 813 of the center position 809 to a perpendicular intersection of side D of the offset mirror 811 is L/2−a2. In the example of FIG. 10, OFFSET2=√2̅*̅a̅2̅²̅.

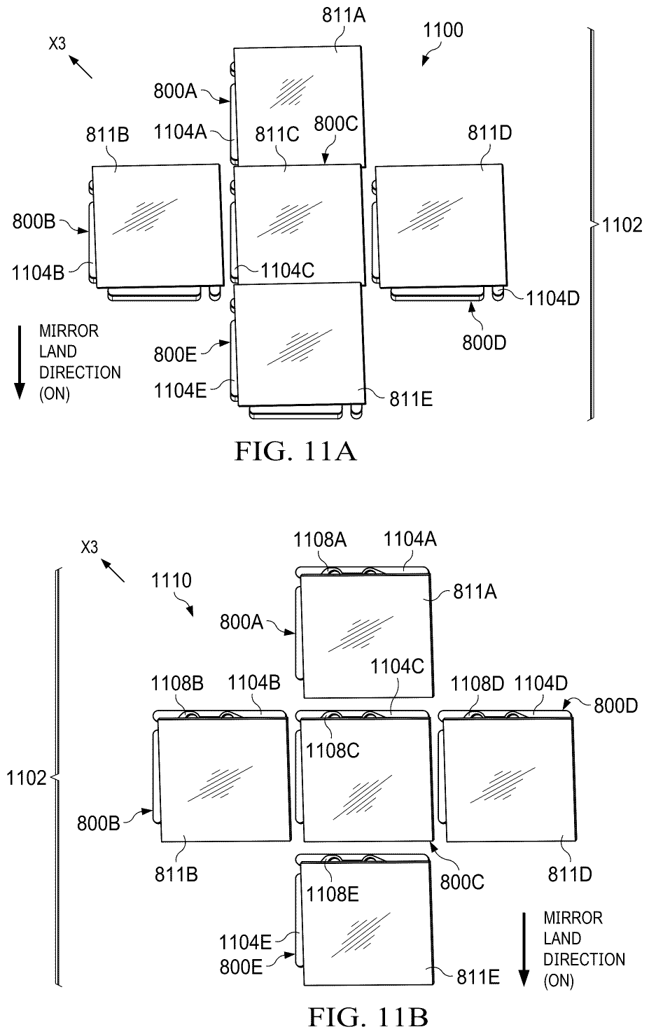

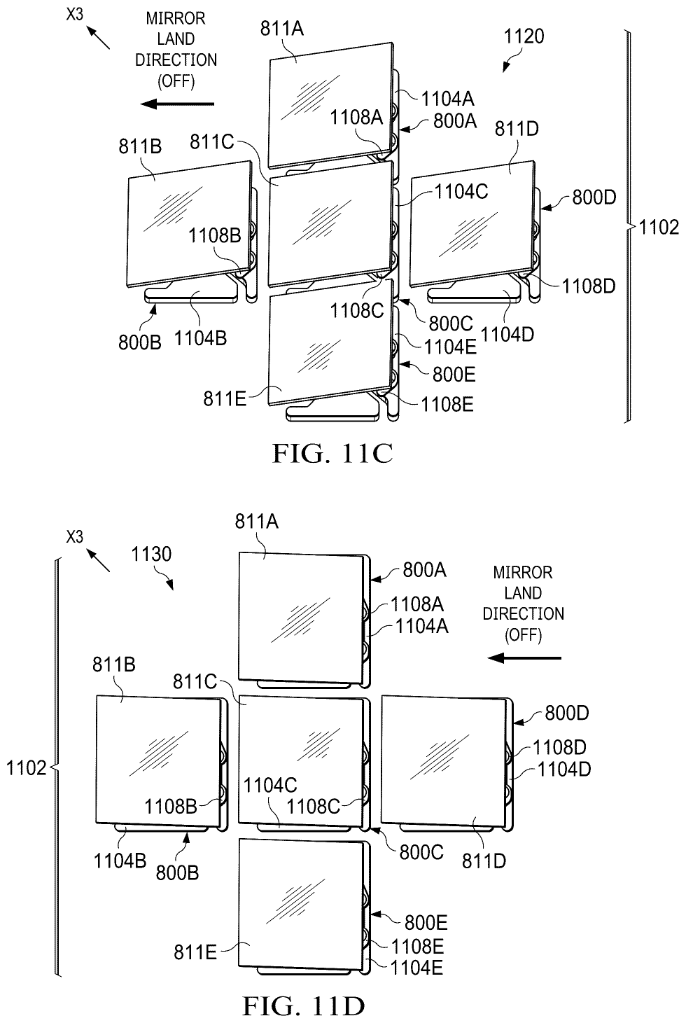

With OFFSET2 in the −X3 direction and related spacings a2, the offset mirror 811 improves coverage of a target mechanical layer component (e.g., the first raised electrode 812A, the second raised electrode 812B, the cantilever hinge 808, and/or springs tips 816A to 816C), a target electrode layer component (e.g., the first address electrode 802A, the second address electrode 802B, and/or the bias electrode 804), and/or a via (e.g., the mirror via 818, the hinge vias 806, the spring tip vias 314A to 314C, the first electrode vias 810A and/or the second electrode vias 810B) relative to a projection aperture. In some examples, OFFSET2 in the −X3 direction is approximately 0.318 micrometers and the spacing a2 is approximately 0.225 micrometers for a 5.4 μm pixel size. In this first example, OFFSET2 is approximately 5.89% of the pixel size. In another examples, OFFSET2 in the −X3 direction is approximately 0.389 micrometers and the spacing a2 is approximately 0.275 micrometers for a 5.4 μm pixel size. In this second example, OFFSET2 is approximately 7.2% of the pixel size. In different examples, the offset, the spacing a1, and/or the pixel size may vary. Example pixel sizes may range from 16 μm pixels down to 2.7 μm pixels or smaller. FIGS. 11A to 11D are different views 1100, 1110, 1120, and 1130 of a pixel array 1102 based on MEMS device 800 with respective offset mirrors 811A to 811E. Each of the MEMS devices 800A to 800E is an example of the MEMS device 800 in FIG. 8. Each of the respective offset mirrors 811A to 811E is an example of the offset mirror 811 in FIG. 8. In FIGS. 11A to 11D, the offset mirrors 811A to 811E are offset in the −X3 direction relative to a center position (e.g., the center position 809 in FIGS. 8 and 10).

FIG. 11A is an incoming light angle view 1100 of part of the pixel array 1102 with the offset mirrors 811A to 811E in an on position (the mirror land direction or tilt for the on position is in the down direction in FIG. 11A). In the example of FIG. 11A, the offset mirrors 811A to 811E, and electrode layer component portions 1104A to 1104E of the respective MEMS devices 800A to 800E are represented. In FIGS. 11A to 11D, the offset mirrors 811A to 811E are offset relative to other MEMS device layers including respective electrode layers (e.g., each respective electrode layer of a MEMS device such as the MEMS device 800 in FIG. 8) and respective mechanical layers (e.g., each respective mechanical layer of a MEMS device such as the MEMS device 800 in FIG. 8). Each of the electrode layer component portions 1104A to 1104E may be part of a first address electrode (e.g., the first address electrode 802A in FIG. 8), part of a second address electrode (e.g., the second address electrode 802B in FIG. 8), or part of a bias electrode (e.g., the bias electrode 804 in FIG. 8).

FIG. 11B is a projection aperture view 1100 of the pixel array 1102 with the offset mirrors 811A to 811E in an on position (the mirror land direction or tilt for the on position is in the down direction in FIG. 11B). In the example of FIG. 11B, the offset mirrors 811A to 811E, the electrode layer component portions 1104A to 1104E, and mechanical layer component portions 1108A to 1108E of the respective MEMS devices 800A to 800E are represented. Each of the mechanical layer component portions 1108A to 1108E may be part of a cantilever hinge (e.g., the cantilever hinge 808 in FIG. 8), part of a spring tip (e.g., the spring tips 816A to 816C in FIG. 8), part of a first raised electrode (e.g., the first raised electrode 812A in FIG. 8), or part of a second raised electrode (e.g., the second raised electrode 812B in FIG. 8).

FIG. 11C is an incoming light angle view 1120 of the pixel array 1102 with the offset mirrors 811A to 811E in an off position (the mirror land direction or tilt for the off position is in the left direction in FIG. 11C). In the example of FIG. 11C, the offset mirrors 811A to 811E, the electrode layer component portions 1104A to 1104E, and the mechanical layer component portions 1108A to 1108E of the respective MEMS devices 800A to 800E are represented.

FIG. 11D is a projection aperture view 1130 of the pixel array 1102 with the offset mirrors 811A to 811E in the off position (the mirror land direction or tilt for the off position is in the left direction in FIG. 11D). In the example of FIG. 11C, the offset mirrors 811A to 811E, the electrode layer component portions 1104A to 1104E, and the mechanical layer component portions 1108A to 1108E of the respective MEMS devices 800A to 800E are represented.

In the incoming light angle view 1100 of FIG. 11A, with the offset mirrors 811A to 811E in the on position, most MEMS device components below the offset mirrors 811A to 811E are not visible except some electrode layer component portions such as the electrode layer component portions 1104A to 1104E. In the projection aperture view 1110 of FIG. 11B, with the offset mirrors 811A to 811E in the on position, most MEMS device components below the offset mirrors 811A to 811E are not visible except some electrode layer component portions such as the electrode layer component portions 1104A to 1104E and some mechanical layer component portions such as the mechanical layer component portions 1108A to 1108E. In the incoming light angle view 1120 of FIG. 11C, with the offset mirrors 811A to 811E in the off position, most MEMS device components below the offset mirrors 811A to 811E are not visible except some electrode layer component portions such as the electrode layer component portions 1104A to 1104E and some mechanical layer component portions such as the mechanical layer component portions 1108A to 1108E. Although more of the electrode layer component portions 1104A to 1104E and more of the mechanical layer component portions 1108A to 1108E are visible in the incoming light angle view 1120 of FIG. 11C, the incoming light view 1120 does not significantly affect the amount of stray light directed to a projection aperture. Exposure of electrode layer component portions 1104A to 1104E and/or the mechanical layer component portions 1108A to 1108E relative to a projection aperture is more relevant than exposure from an incoming light view. In the projection aperture view 1130 of FIG. 11D, with the offset mirrors 811A to 811E in the off position, most MEMS device components below the offset mirrors 811A to 811E are not visible except some electrode layer component portions such as the electrode layer component portions 1104A to 1104E and some mechanical layer component portions such as the mechanical layer component portions 1108A to 1108E. Compared to mirrors aligned with center positions (e.g., the center position 809 in FIGS. 8 and 10), the offset mirrors 811A to 811E cover more electrode layer component portions (e.g., more of the electrode layer component portions 1104A to 1104E) and/or mechanical layer component portions (e.g., more of the mechanical layer component portions 1108A to 1108E) relative to a projection aperture, which improves contrast.

Compared to mirrors in a centered position, the offset mirrors 811A to 811E in FIGS. 11A to 11D cover more mechanical layer component portions such as the mechanical layer component portions 1108A to 1108E. Compared to mirrors aligned with a center position, the offset mirrors 811A to 811E in FIGS. 11A to 11D may also cover more electrode layer component portions such as the electrode layer component portions 1104A to 1104E. To improve contrast of a display or projector, increased coverage of mechanical layer components for the projection aperture view 1130 of FIG. 11D has highest priority. This is because scattered light due to visibility of mechanical layer components in the projection aperture view 1130 reaches the aperture (e.g., the projection aperture 138). While full coverage of mechanical layer components for the projection aperture view 1130 is optimal, any coverage improvement of mechanical layer components (relative to centered mirrors) can provide a contrast improvement.

In some examples, electrode layer components are treated with a non-reflective coating, while mechanical layer components (e.g., the cantilever hinge 808, the spring tips 816A to 816C, the first raised electrode 812A, and/or the second raised electrode 812B) are untreated. In some examples, treating mechanical layer components with a non-reflective coating is avoided to ensure consistent movement of the mechanical layer components. In the described examples, the reflectivity of untreated mechanical layer components may result is some extraneous reflected light being directed to a projection aperture. In the described examples, the amount of extraneous reflected light due to mechanical layer components is reduced, at least in a projection aperture view such as the projection aperture view 1130, using offset mirrors (e.g., the offset mirrors 811A to 811E).

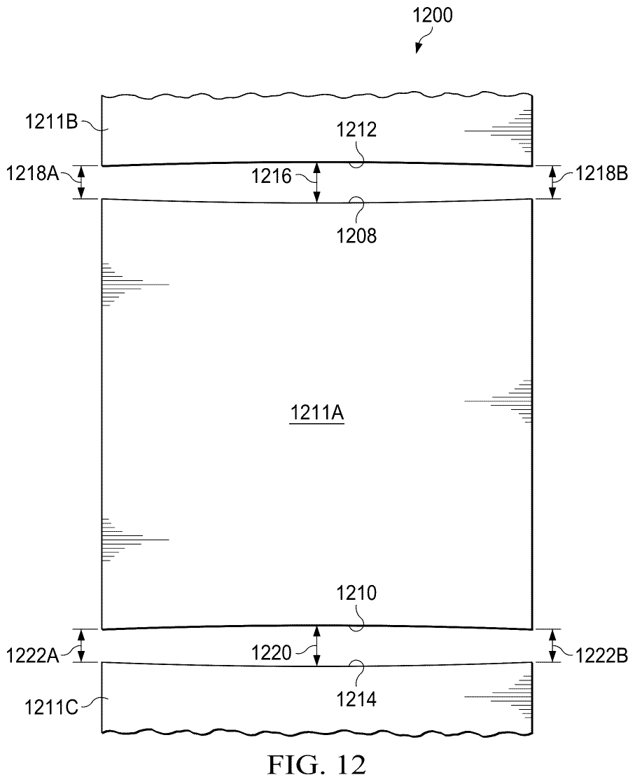

FIG. 12 is a top view 1200 of sculpted offset mirrors 1211A, 1211B, and 1211C in accordance with various examples. In some examples, pixels and related mirrors are organized into reset groups. In such examples, sculpted offset mirrors, such as the sculpted offset mirrors 1211A, 1211B, and 1211C, are sculpted in the direction of and the location of the reset groups. Each of the sculpted offset mirrors 1211A, 1211B, and 1211C is an example of an offset mirror of the pixel array 136 in FIG. 1, the offset mirror 211 in FIGS. 2A and 2B, the offset mirror 311 in FIGS. 3A, 3B, 4, 5, and 6, the offset mirrors 311A to 311E in FIGS. 7A to 7E, the offset mirror 811 in FIGS. 8, 9A, 9B, and 10, or any of the offset mirrors 811A to 811E in FIGS. 11A to 11D. In the example of FIG. 12, the sculpted offset mirror 1211B includes a sculpted top edge 1208 and a sculpted bottom edge 1210. In other examples, all four edges of sculpted offset mirror 1211B may be sculpted. The sculpted offset mirror 1211A has a sculpted bottom edge 1212, and the sculpted offset mirror 1211C has a sculpted top edge 1214. The sculpted edges have a concave shape in this example. Because of the sculpted top edge 1208 and the sculpted bottom edge 1212, the gap between sculpted offset mirrors 1211A and 1211B is larger in the center along the sculpted top edge 1208 and the sculpted bottom edge 1212 than at the ends of the sculpted top edge 1208 and the sculpted bottom edge 1212. The middle gap 1216 is larger than the corner gaps 1218A and 1218B. The middle gap 1216 is a first gap between a first point on sculpted top edge 1208 and the nearest point to the first point on the sculpted offset mirror 1211B. The middle gap 1216 is larger than the corner gap 1218A between a second point on the sculpted top edge 1208 and a nearest point to the second point on the sculpted offset mirror 1211B.

In some examples, the sculpted offset mirrors 1211A, 1211B, and 1211C have a larger gap in the middle so an appropriate distance can be maintained between the edges of the sculpted offset mirrors 1211A, 1211B, and 1211C to prevent damage during operation. In FIG. 12, corner gaps 1218A and 1218B are smaller than the middle gap 1216. Smaller corner gaps allow for a larger total surface area of an SLM to be covered by offset mirrors. As described above, gaps allow light to shine between the offset mirrors, which can cause optical scatter and also heat up the understructure of a MEMS device, which affects the overall temperature of the device. The sculpted top edge 1208 and the sculpted bottom edge 1212 of the sculpted offset mirrors 1211A and 1211B, respectively, provide the larger gap (e.g., the middle gap) where it is most useful while also providing a smaller gap at the corners to cover a larger total surface area of an SLM with offset mirrors. The ratio between the “useful” (reflective) area of a SLM and the complete area of the array, which includes the gaps and the vias, is known as the on-state fill factor. The fill factor is the fraction of a SLM pixel that is actually reflective. A sculpted offset mirror array helps to protect against damage caused by gaps that are too small while also providing a higher fill factor than pixel arrays that have gaps that are too large.

In the example of FIG. 12, the sculpted offset mirror 1211B also has a sculpted bottom edge 1210 that is adjacent to the sculpted top edge 1214 of the sculpted offset mirror 1211C. Because of these sculpted edges, the middle gap 1220 is larger than corner gaps 1222A and 1222B. In some examples, the middle gap 1216 (e.g., a first gap) between a first center of a first edge (the sculpted top edge 1208) and the sculpted offset mirror 1211A. The middle gap 1216 is larger than a corner gap 1222A (e.g., a second gap) between a first end of the sculpted top edge 1208 and the sculpted offset mirror 1211A.

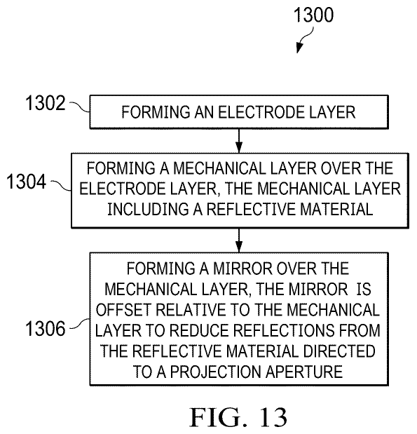

FIG. 13 is a flowchart showing a MEMS device fabrication method 1300 in accordance with various examples. The MEMS device fabrication method 1300 includes forming an electrode layer at block 1302. At block 1304, a mechanical layer is formed over the electrode layer, the mechanical layer including a reflective material. At block 1306, a mirror is formed over the mechanical layer, the mirror is offset relative to the mechanical layer to reduce reflections from the reflective material directed to a projection aperture (e.g., the projection aperture 138 in FIG. 1). With the offset mirror formed at block 1306, the amount of reflections from the reflective material that are directed towards the projection aperture is reduced as described herein.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. A microelectromechanical system (MEMS) device comprising:
a mechanical layer;
a mirror; and
a mirror via coupling the mechanical layer and the mirror, wherein the mirror is laterally offset from the mechanical layer in a direction.

2. The MEMS device of claim 1, wherein the mechanical layer includes a torsion hinge, the mirror has an on position and an off position, and the mirror in the off position increases coverage of the torsion hinge relative to a projection aperture compared to a mirror aligned with a center position.

3. The MEMS device of claim 2, wherein the mirror is laterally offset along the direction by at least 0.15 μm relative to the center position.

4. The MEMS device of claim 1, wherein the mechanical layer includes a cantilever hinge, the mirror has an on position and an off position, and the mirror in the off position increases coverage of the cantilever hinge relative to a projection aperture compared to a mirror aligned with a center position.

5. The MEMS device of claim 4, wherein the mirror is laterally offset along the direction by at least 0.225 μm relative to the center position.

6. The MEMS device of claim 1, wherein the mechanical layer includes a spring tip, the mirror has an on position and an off position, and the mirror in the off position increases coverage of the spring tip relative to a projection aperture compared to a mirror aligned with a center position.

7. The MEMS device of claim 1, wherein the mirror via is centered relative to the mechanical layer.

8. The MEMS device of claim 1, wherein the mirror has sculpted edges.

9. A microelectromechanical system (MEMS) device comprising:
an electrode layer;
a mechanical layer;
hinge vias coupling the electrode layer and the mechanical layer;
a mirror; and
a mirror via coupling the mechanical layer and the mirror, the mirror having a first position when the MEMS device is in an on state, the mirror having a second position when the MEMS device is in an off state, and the mirror laterally offset relative to the mechanical layer in a direction.

10. The MEMS device of claim 9, wherein the mechanical layer includes a torsion hinge, the mirror has an on position and an off position, and the mirror in the off position increases coverage of the torsion hinge relative to a projection aperture compared to a mirror aligned with a center position.

11. The MEMS device of claim 9, wherein the mechanical layer includes a cantilever hinge, the mirror has an on position and an off position, and the mirror in the off position increases coverage of the cantilever hinge relative to a projection aperture compared to a mirror aligned with a center position.

12. The MEMS device of claim 9, wherein the mechanical layer includes a raised electrode, the mirror has an on position and an off position, and the mirror in the off position increases coverage of the raised electrode relative to a projection aperture compared to a mirror aligned with a center position.

13. The MEMS device of claim 9, wherein the mechanical layer includes a spring tip, the mirror has an on position and an off position, and the mirror in the off position increases coverage of the spring tip relative to a projection aperture compared to a mirror aligned with a center position.

14. The MEMS device of claim 9, wherein the mirror via is centered relative to the mechanical layer.

15. A microelectromechanical system (MEMS) device comprising:
an electrode layer;
a mechanical layer;
hinge vias coupling the electrode layer and the mechanical layer;
a mirror; and
a mirror via coupling the mechanical layer and the mirror, wherein the mirror is laterally offset relative to the mechanical layer in a direction.

16. The MEMS device of claim 15, wherein the mechanical layer includes a torsion hinge and spring tips, the mirror has an on position and an off position, and the mirror in the off position increases coverage of the torsion hinge relative to a projection aperture compared to a mirror aligned with a center position.

17. The MEMS device of claim 15, wherein the mechanical layer includes a cantilever hinge and a spring tip, the mirror has an on position and an off position, and the mirror in the off position increases coverage of the cantilever hinge relative to a projection aperture compared to a mirror aligned with a center position.

18. The MEMS device of claim 15, wherein the mechanical layer includes a raised electrode, the mirror has an on position and an off position, and the mirror in the off position increases coverage of the raised electrode relative to a projection aperture compared to a mirror aligned with a center position.

19. The MEMS device of claim 15, wherein the mechanical layer includes a spring tip, the mirror has an on position and an off position, and the mirror in the off position increases coverage of the spring tip relative to a projection aperture compared to a mirror aligned with a center position.

20. The MEMS device of claim 15, wherein the mirror via is centered relative to the mechanical layer.
